(19) United States
(12) Patent Application Publication
(10) Pub. No.: US 2015/0255589 A1
(43) Pub. Date: Sep. 10, 2015

(54) INDIUM-CONTAINING CONTACT AND BARRIER LAYER FOR III-NITRIDE HIGH ELECTRON MOBILITY TRANSISTOR DEVICES

(71) Applicant: TOSHIBA CORPORATION, Tokyo (JP)

(72) Inventor: William Fenwick, Livermore, CA (US)

(73) Assignee: TOSHIBA CORPORATION, Tokyo (JP)

(21) Appl. No.: 14/203,165

(22) Filed: Mar. 10, 2014

(51) Int. Cl. H01L 29/778; H01L 29/45; H01L 21/02; H01L 29/66; H01L 29/20

(52) U.S. Cl. CPC H01L 29/778; H01L 29/66431; H01L 29/2003; H01L 21/0254; H01L 21/0262; H01L 29/452

(57) ABSTRACT

A high electron mobility transistor device includes a substrate, a buffer layer on the substrate, a channel layer on the buffer layer, and a contact and barrier layer on the channel layer, the contact and barrier layer being made of indium aluminum nitride with a plurality of indium precipitates exposed on the surface of the contact and barrier layer. The plurality of indium precipitates exposed on the surface of the contact and barrier layer enable metal contacts to be formed directly on the contact and barrier layer with reliable and repeatable electrical performance. The contact and barrier layer may be epitaxially grown in a metal organic chemical vapor deposition process where a ratio of group-V precursors to group-III precursors is low and a flow rate of an indium precursor is greater than a flow rate of an aluminum precursor.

### FIELD OF THE INVENTION

The invention relates generally to high electron mobility transistors and more particularly to an indium-containing contact and barrier layer for III-V high electron mobility transistors.

### BACKGROUND

The high electron mobility transistor (HEMT) is one type of a field effect transistor (FET) in which a hetero-junction between a channel layer and a barrier layer whose electron affinity is smaller than that of the channel layer is formed. A two-dimensional electron gas (2DEG) forms in the channel layer of a III-nitride HEMT device due to the mismatch in polarization field at the channel-barrier interface. The 2DEG has a high electron mobility that facilitates high-speed switching. In a typical depletion mode HEMT device, a negatively-biased voltage may be applied to the gate to deplete the 2DEG and thereby turn off the device. A III-V HEMT is one made of materials in column III of the periodic table such as aluminum, gallium, and indium, and materials in column V of the periodic table such as nitrogen, phosphorous, and arsenic.

FIG. 1A is a cross-sectional diagram of a prior art structure for an HEMT device. Substrate 110 can be silicon, silicon carbide, sapphire, or other appropriate material. Because it is difficult to epitaxially grow a high-quality gallium nitride semiconductor crystal layer on substrate 110 due to poor lattice matching between the gallium nitride and the substrate material, buffer layer 112 of gallium nitride, aluminum gallium nitride, or aluminum nitride may be deposited on substrate 110 which improves the regularity of the crystal structure of subsequently grown gallium nitride layers. Epitaxial growth of gallium nitride (GaN) forms a channel layer 114 on buffer layer 112. Next, a barrier layer 116, also known as an electron supply layer, may be formed by epitaxial growth on channel layer 114. Barrier layer 116 may be made of aluminum gallium nitride (AlₓGa₁₋ₓN) or indium aluminum nitride (InₓAl₁₋ₓN). Contacts 126 formed on barrier layer 116 act as the source and drain of the device. An insulating layer 128 of silicon nitride (SiₓN_{y}) formed on barrier layer 116 prevents current from flowing between a gate structure 130 and barrier layer 116. Gate structure 130 may be formed of nickel (Ni). Accordingly with the foregoing structure, a 2DEG forms on the channel layer side of the interface between channel layer 114 and barrier layer 116, allowing current to flow between contacts 126. A negative voltage (relative to substrate 110) may be applied to gate structure 130 to deplete the 2DEG and shut off the flow of current between contacts 126 to turn off the device.

In the FIG. 1A embodiment, contacts 126 include multiple layers of different metals. Metal deposition followed by etching creates contacts 126. A first contact layer 118 forms an electrical contact with barrier layer 116 because the titanium of first contact layer 118 attracts nitrogen atoms out of barrier layer 116 during annealing, leaving vacancies in barrier layer 116 and creating titanium nitride (TiN) and an alloy of aluminum and titanium at the interface between first contact layer 118 and barrier layer 116. Contacts 126 also include a second contact layer 120 of aluminum, a third contact layer 122 of nickel, and a fourth contact layer 124 of gold. The gold prevents oxidation of the titanium and aluminum layers, and the nickel in third contact layer 122 acts as a diffusion barrier that prevents the gold from diffusing into the titanium and aluminum layers. Contacts 126 are typically annealed at a temperature of 700-800° C.

A barrier layer of InₓAl₁₋ₓN can have an aluminum concentration of 85% or greater, and has a correspondingly large bandgap (E_{g}>5.0 eV). An InₓAl₁₋ₓN barrier layer has a higher carrier concentration and lower sheet resistance than a barrier layer formed of AlₓGa₁₋ₓN. An InₓAl₁₋ₓN barrier layer also has no piezoelectric effects in contrast to an AlₓGa₁₋ₓN barrier layer, which has a strong piezoelectric field. Thus a device having an InₓAl₁₋ₓN barrier layer may be preferred for some high voltage power electronics applications. But the large bandgap of InₓAl₁₋ₓN creates a high barrier to electron flow at the interface between the InₓAl₁₋ₓN barrier layer and the metal of first contact layer 118, as illustrated in FIG. 1B, where E_{C} is the conduction band edge, E_{V} is the valance band edge, and E_{F} is the Fermi energy. Thus it is more difficult to fabricate an ohmic contact to InₓAl₁₋ₓN than to GaN or AlₓGa₁₋ₓN, and the performance of contacts 126 formed on an InₓAl₁₋ₓN barrier layer is often not very reliable or repeatable. The thermal and chemical stability of InₓAl₁₋ₓN may also suppress or prevent alloy formation upon annealing of a metal contact, leaving a contact with a slight rectifying behavior (i.e., a non-linear or Schottky contact) instead of an ohmic contact. As shown in FIG. 1C, an ohmic contact has a linear current-voltage characteristic 150 and a Schottky contact has a non-linear current-voltage characteristic 152.

FIG. 2A is a cross-sectional diagram of another prior art structure for an HEMT device. The FIG. 2A device includes a cap layer 132 between barrier layer 116 and contacts 126. Cap layer 132 can be made of GaN, as shown, or of other materials having a lower bandgap than InₓAl₁₋ₓN such as indium nitride (InN), or indium gallium nitride (InₓGa₁₋ₓN). FIG. 2B illustrates the relative bandgaps of the GaN channel layer 114, barrier layer 116, and cap layer 132, where E_{C} is the conduction band edge, E_{V} is the valance band edge, and E_{F} is the Fermi energy. With its lower bandgap, cap layer 132 forms a more reliable and repeatable contact with contact layer 118 than barrier layer 116 made of InₓAl₁₋ₓN. But including cap layer 132 in the device requires an additional epitaxial growth step in the fabrication process of the device. Also, differences in polarization between cap layer 132 and barrier layer 116 can lead to the formation of a bound charge at the interface of the two layers, which may screen the 2DEG, decreasing the sheet carrier concentration in the 2DEG and thus degrading performance of the device.

Thus there is a need to improve the formation of reliable metal contacts on an HEMT device having indium aluminum nitride barrier layer without additional processing steps.

### SUMMARY

A high electron mobility transistor device includes a substrate, a buffer layer on the substrate, a channel layer on the buffer layer, and a contact and barrier layer on the channel layer, the contact and barrier layer being made of indium aluminum nitride with a plurality of indium precipitates exposed on the surface of the contact and barrier layer. The plurality of indium precipitates extend above the surface of the contact and barrier layer and also extend into the bulk of the contact and barrier layer, thus bridging the surface of the contact and barrier layer. The plurality of indium precipitates bridging the surface of the contact and barrier layer enable metal contacts to be formed directly on the contact and barrier layer with reliable and repeatable electrical performance. The contact and barrier layer is epitaxially grown using a metal organic chemical vapor deposition (MOCVD) process having growth conditions where a ratio of group-V precursors to group-III precursors is low and the flow rate of an indium precursor is greater than the flow rate of an aluminum precursor.

A method of fabricating a high electron mobility transistor device includes forming a contact and barrier layer of indium aluminum nitride on a channel layer in growth conditions such that a plurality of indium precipitates exposed on the surface of the contact and barrier layer are formed. The plurality of indium precipitates extend above the surface of the contact and barrier layer and also extend into the bulk of the contact and barrier layer, thus bridging the surface of the contact and barrier layer. In one embodiment, a MOCVD process may be used to form the contact and barrier layer in growth conditions where a ratio of group-V precursors to group-III precursors is low and the flow rate of an indium precursor is greater than the flow rate of an aluminum precursor. The method further includes forming one or more metal contacts directly on the contact and barrier layer. In one embodiment, forming the contact and barrier layer includes epitaxially growing a first portion of indium aluminum nitride without indium precipitates and epitaxially growing a second portion of indium aluminum nitride on the first portion of indium aluminum nitride, the second portion of indium aluminum nitride containing the plurality of indium precipitates.

### BRIEF DESCRIPTION OF THE DRAWINGS

FIG. 1A is a cross-sectional diagram of a prior art structure for a HEMT device.

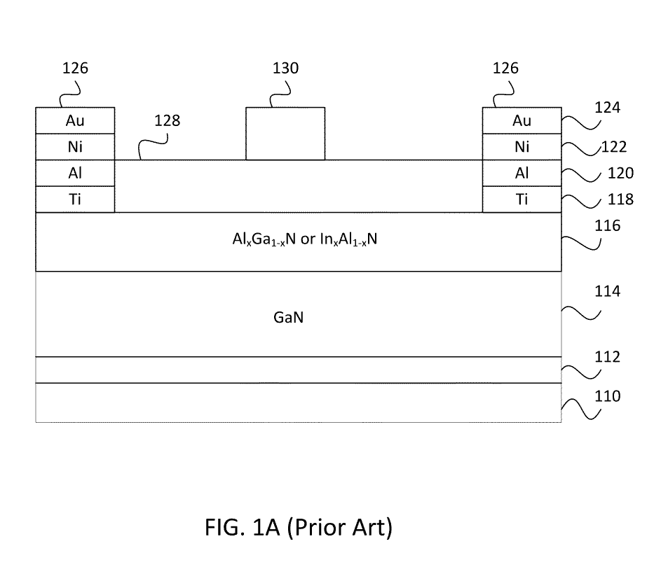

FIG. 1B is a diagram illustrating effect of the high bandgap of indium aluminum nitride to electron flow at a metal-semiconductor interface.

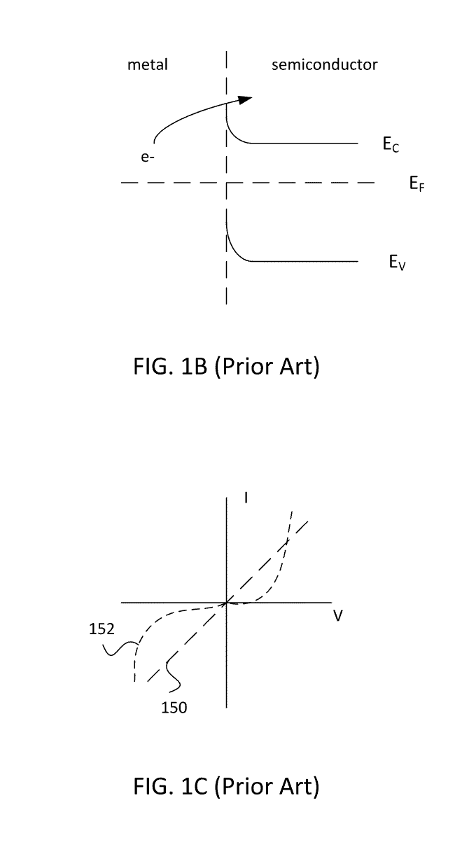

FIG. 1C is a diagram showing an ohmic current-voltage response and a Schottky current-voltage response.

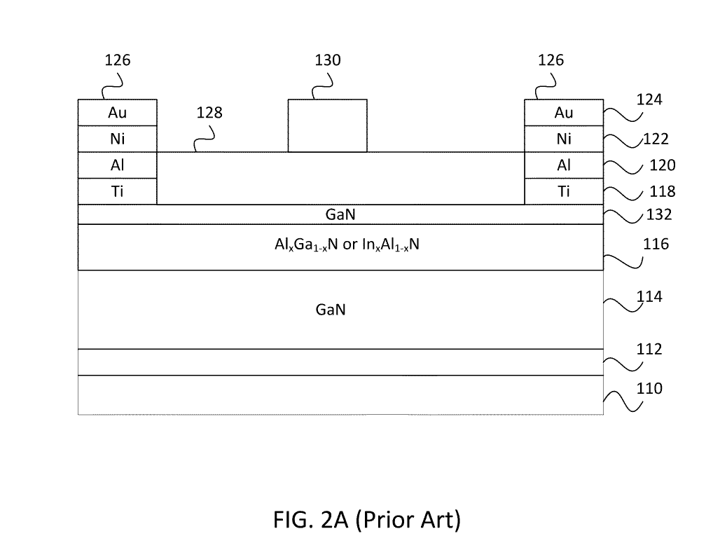

FIG. 2A is a cross-sectional diagram of another prior art structure for a HEMT device.

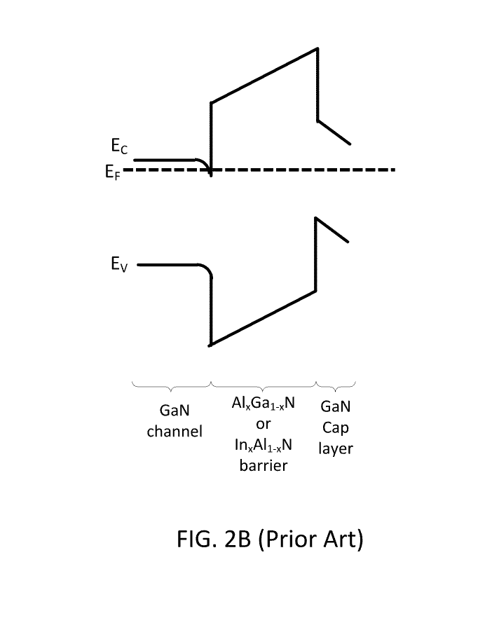

FIG. 2B is a band diagram of the HEMT device of FIG. 2A.

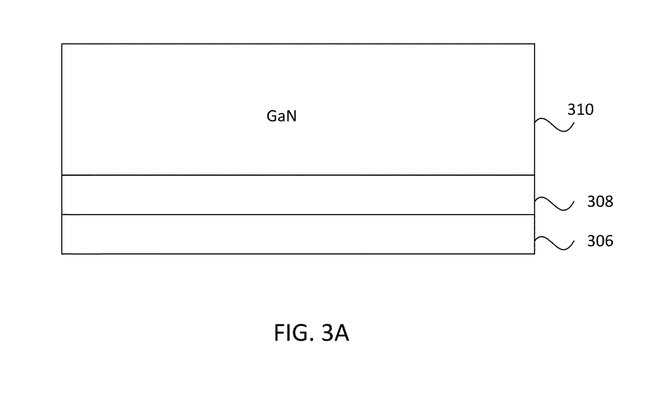

FIGS. 3A-3D are cross-sectional diagrams of one embodiment of a HEMT device having an indium-containing contact and barrier layer, according to the invention.

FIG. 4 is a magnified top view of one embodiment of an indium-containing contact and barrier layer, according to the invention.

FIG. 5 is a graph showing one embodiment of a relationship between trimethylindium flow and ammonia flow in forming an indium-containing contact and barrier layer, according to the invention.

FIG. 6A is a top view of one embodiment of an indium-containing contact and barrier layer according to the invention with metal contacts formed thereon for testing electrical characteristics.

FIG. 6B is a graph showing a current-voltage curve characteristic of the FIG. 6A embodiment of an indium-containing contact and barrier layer, according to the invention.

FIG. 6C is a graph showing a current-voltage curve characteristic of a typical indium aluminum nitride barrier layer.

### DETAILED DESCRIPTION

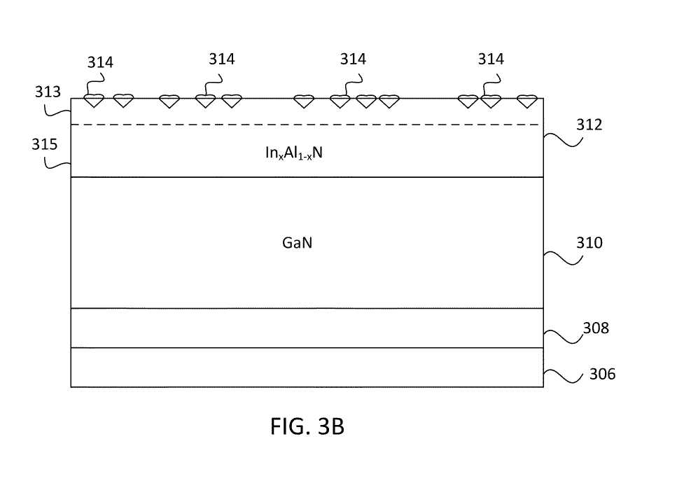

FIG. 3A is a cross-sectional diagram of a portion of an HEMT device, according to one embodiment of the invention. Epitaxial growth of gallium nitride forms a channel layer 310 on a buffer layer 308 on a semiconductor substrate 306. Semiconductor substrate 306 can be made of silicon, silicon carbide, sapphire, or other appropriate material. Buffer layer 308 is made of deposited gallium nitride, aluminum gallium nitride, or aluminum nitride to improve the quality of the crystal structure of subsequently-grown gallium nitride channel layer 310.

FIG. 3B is a cross-sectional diagram of a portion of an HEMT device including one embodiment of an indium-containing contact and barrier layer, according to the invention. An indium-containing contact and barrier layer 312 is epitaxially grown on channel layer 310. Layer 312 is made of InₓAl₁₋ₓN which has indium precipitates 314 located near the upper surface of the layer. Indium precipitates 314 are metallic indium that forms clusters or islands that protrude slightly above the surface of layer 312 and also extend down into layer 312, thus bridging the surface of layer 312. The top surface of each of indium precipitates 314 is exposed at the surface of contact and barrier layer 312.

Indium precipitates 314 may be formed by adjusting the epitaxial growth conditions of contact and barrier layer 312 such that a ratio of the flow rate of group-V precursors to the flow rate of group-III precursors is low, and the flow rate of an indium precursor is greater than the flow rate of an aluminum precursor, as further described below. In one embodiment, a metal organic chemical vapor deposition (MOCVD) process epitaxially grows layer 312 where the epitaxial growth conditions are set such that the ratio of the flow rate of ammonia (NH₃) to the combined flow rates of trimethylindium ((CH₃)₃In or TMIn) and trimethylaluminum ((CH₃)₃Al or TMAI) is low, for example about 1400 and the flow rate of trimethylindium is greater than the flow rate of trimethylaluminum. Under these growth conditions, some of the available indium atoms form precipitates 314 bridging the surface of layer 312, where each indium precipitate 314 has an exposed surface above the surface of layer 312 and also extends below the surface of layer 312.

In one embodiment, a process for growing contact and barrier layer 312 utilizes a K465i™ MOCVD system made by Veeco Instruments Inc. The precursor materials used to form contact and barrier layer 312 include trimethylaluminum, trimethylindium, and ammonia. One embodiment of settings for the epitaxial growth conditions in a K465i™ system to form contact and barrier layer 312, which includes indium precipitates 314, is set forth in Table 1.

TABLE 1

| Precursor | Flow Rate | Units |
|---|---|---|
| TMAl (trimethylaluminum) | 29.0 | μmol/min |
| TMIn (trimethylindium) | 129.8 | μmol/min |
| NH₃ (ammonia) | 2.23E+05 | μmol/min |

The growth conditions in Table 1 reflect a V/III (“five-three”) ratio of 1404.2. The V/III ratio is the ratio of group V precursors to group III precursors going into the growth chamber of the MOCVD system. For the values in Table 1, the flow rate of the ammonia divided by the combined flow rates of the trimethylaluminum and the trimethylindium produces a V/III ratio of 1404.2. A V/III ratio of 1404.2 in the context of MOCVD epitaxial growth of III-nitride materials is a low ratio. A V/III ratio for growing gallium nitride (GaN) using an MOCVD process is typically in the range of 5,000-10,000, and a V/III ratio for growing indium nitride (InN) using an MOCVD process is typically 20,000 or larger. A V/III ratio of about 1400 or less for growing indium aluminum nitride is thus considered low, particularly in comparison to a typical V/III ratio for growing indium nitride, another indium-containing material.

For formation of indium precipitates 314 in an indium aluminum nitride layer 312 grown using an MOCVD process, in addition to having a low V/III ratio, the flow rate of the indium precursor should be greater than the flow rate of the aluminum precursor. The growth conditions in Table 1 reflect a ratio of the flow rates of the indium precursor to the aluminum precursor of 4.5. Other growth conditions using values of the precursors TMAI, TMIn, and NH₃ other than those set forth in Table 1 that result in a V/III ratio of about 1400 or less and an indium-to-aluminum ratio of about 4 or greater will also cause indium precipitates 314 to form.

In one embodiment, an MOCVD process epitaxially grows the entirety of contact and barrier layer 312 under conditions such that indium precipitates 314 will form bridging the surface of layer 312. In another embodiment, an MOCVD process epitaxially grows a first portion of layer 312 under typical InₓAl₁₋ₓN growth conditions that will not produce indium precipitates 314. Then, the growth conditions of the MOCVD process are adjusted to grow an additional portion of layer 312 having indium precipitates 314 bridging the surface of contact and barrier layer 312. In this embodiment, the first portion of layer 312 grown under typical InₓAl₁₋ₓN growth conditions will typically use a lower flow rate of TMIn than the flow rate of TMIn needed to produce the low V/III ratio growth conditions for forming indium precipitates 314. Thus growing a portion of contact and barrier layer 312 under typical growth conditions uses a smaller total amount of TMIn material than growing the entirety of contact and barrier layer 312 under conditions where indium precipitates 314 form. Under the growth conditions shown in Table 1 above, a minimum thickness for a contact and barrier layer 312 such that indium precipitates 314 will form is about 100 Angstroms. So in one example, if a desired total thickness of a contact and barrier layer is about 300 Angstroms, a 200 Angstrom first portion 315 of InₓAl₁₋ₓN can be grown under typical growth conditions and then the growth conditions can be modified such that indium precipitates will form to grow a 100 Angstrom second portion 313 of InₓAl₁₋ₓN with indium precipitates bridging the surface of the layer.

FIG. 3C is a cross-sectional diagram of a portion of an HEMT device with metal contacts formed on an indium-containing contact and barrier layer, according to one embodiment of the invention. Metal contacts 316 act as the source and drain for the device. In one embodiment, metal contacts 316 include a plurality of metal layers, for example Ti/Al/Ni/Au. Indium precipitates 314 provide a three-dimensional metal-semiconductor interface that can form reliable ohmic contacts with metal contacts 316. The portion of an indium precipitate 314 that is exposed above the surface of contact and barrier layer 312 can form a metal-to-metal contact with a source or drain contact formed on it, and the body of indium precipitate 314 that is below the surface of and enclosed within contact and barrier layer 312 forms a contact with the InₓAl₁₋ₓN of layer 312. Indium precipitates 314 form ohmic contacts with metal contacts 316, which improves the overall linearity of the current-voltage response between contacts 316 and contact and barrier layer 312.

FIG. 3D is a cross-sectional diagram of a HEMT device with an indium-containing contact and barrier layer, according to one embodiment of the invention. In FIG. 3D, a deposition process forms an insulating layer 318 between contacts 316. Insulating layer 318 may be made of silicon nitride (SiₓN_{y}), or other materials such as aluminum oxide or hafnium oxide. A deposition process followed by etching forms a gate structure 320 on insulating layer 318. Indium precipitates 314 in contact and barrier layer 312 do not interfere with formation of the 2DEG in channel layer 310 when a voltage is applied to gate structure 320.

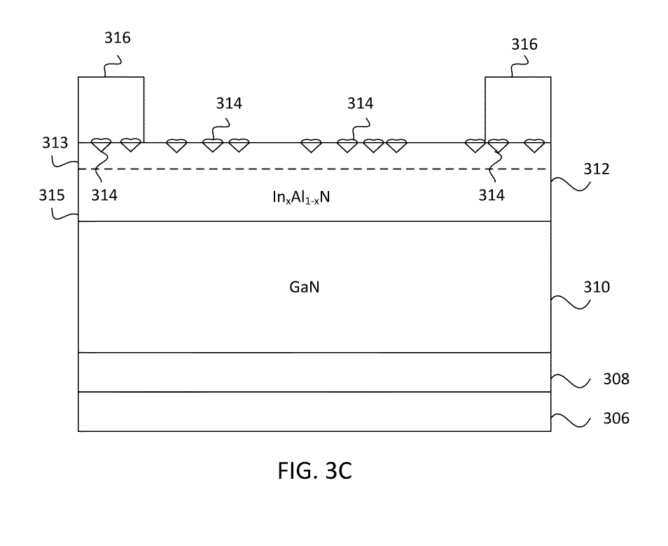

FIG. 4 is a magnified top view of one embodiment of an indium-containing contact and barrier layer, according to the invention. In the FIG. 4 embodiment, indium precipitates 412 that are exposed and protrude above the surface of indium-containing contact and electron supply layer 410 can be observed. Indium precipitates 412 can be observed in the indium-containing contact and barrier layer 410 using transmission electron microscopy (TEM), atomic force microscopy (AFM), or some similar technique that shows the surface of layer 410 at a high magnification.

Precipitates 412 are substantially randomly distributed across the surface of layer 410. Precipitates 412 have various sizes, ranging from about 10 nanometers to 350 nanometers in diameter measured at the surface of layer 410. The size and number of precipitates 412 are distributed across the surface of layer 410 such that there is a high likelihood that a metal contact formed anywhere on layer 410 will be formed over one or more of indium precipitates 412. Each indium precipitate 412 exposed at the surface of layer 412 can establish an ohmic contact with a metal contact layer that is deposited on top of the indium precipitate 412.

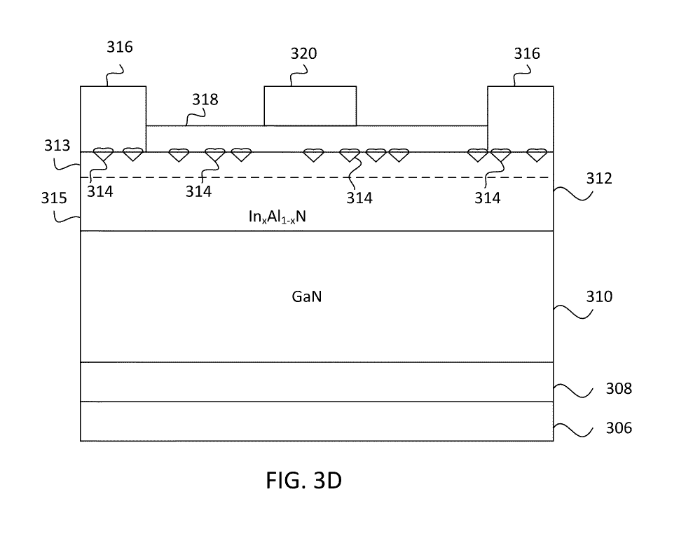

FIG. 5 is a graph showing one embodiment of a relationship between trimethylindium flow and ammonia flow in forming an indium-containing contact and barrier layer, according to the invention. The axes of FIG. 5 are not on the same scale. The shaded region 510 of FIG. 5 is a pictorial representation of the process window in an MOCVD process for formation of an indium aluminum nitride layer having indium precipitates bridging the surface of the layer. In one embodiment, an MOCVD process with ammonia (NH₃), trimethylaluminum (TMAI), and trimethylindium (TMIn) as precursor materials epitaxially grows contact and barrier layer 312 (FIG. 3) having indium precipitates 314. In such a process, for a given flow rate of ammonia, a low V/III ratio, for example about 1400 or lower, that will cause the formation of indium precipitates 314 can be achieved by increasing the flow rate of the trimethylindium. For a given flow rate of trimethylindium, a low V/III ratio that will cause the formation of indium precipitates 314 can be achieved by decreasing the flow rate of the ammonia. The specific low V/III ratio of precursor materials used to grow layer 312 can vary according to a desired amount of indium precipitates 314 and the specific epitaxial growth process type and specific tool used.

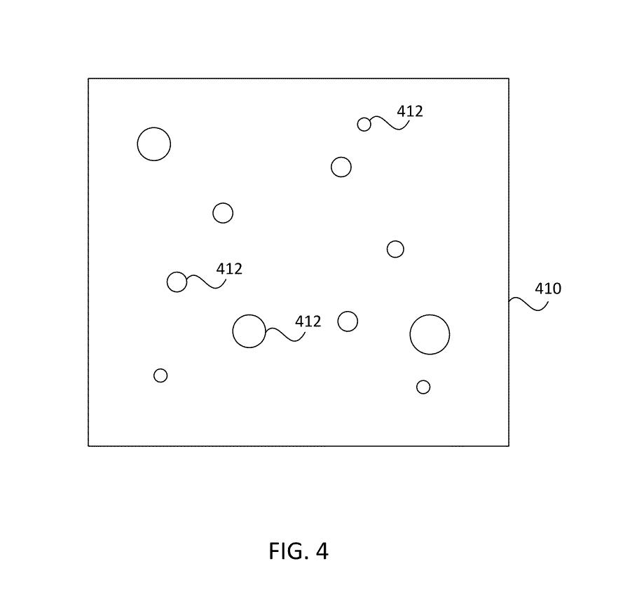

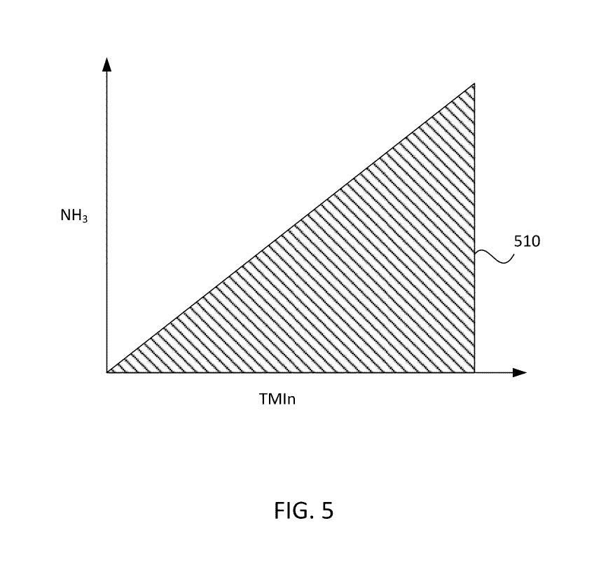

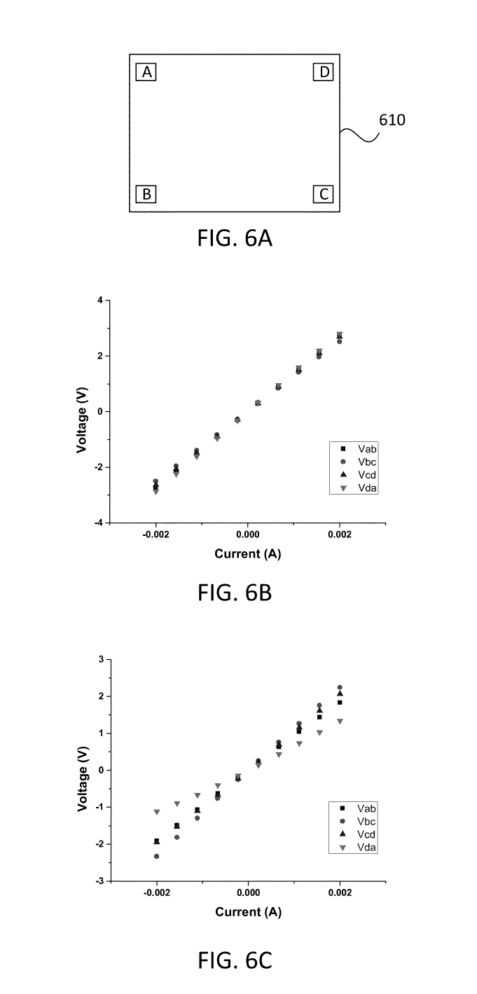

FIG. 6A is a top view of one embodiment of an indium-containing contact and barrier layer 610 according to the invention with metal contacts formed thereon for testing electrical characteristics. Like contact and barrier layer 312 of FIGS. 3B-3D, layer 610 includes a plurality of indium precipitates (not shown in FIG. 6A) exposed at the surface of layer 610. In the FIG. 6A embodiment, each contact is formed from the stacked metal layers Ti/Al/Ni/Au. FIG. 6B is a graph showing a current-voltage curve characteristic of indium-containing contact and barrier layer 610. FIG. 6B shows voltage measurements between the four Ti/Al/Ni/Au contacts (labeled A, B, C, & D in FIG. 6A) formed on the surface of contact and barrier layer 610 at ten different current levels. As shown, the current-voltage characteristic of contact and barrier layer 610 is substantially linear, which is characteristic of an ohmic contact. An ohmic contact has a more predictable and reliable response to a given current or voltage than a Schottky contact with a non-linear current-voltage characteristic. Also, the variation among the voltage measurements of the different pairs of contacts at the same current level is small, which shows that the performance of contacts formed on layer 610 have good repeatability.

FIG. 6C is a graph showing a current-voltage curve characteristic of a typical indium aluminum nitride barrier layer that does not contain indium precipitates. FIG. 6B shows voltage measurements between four Ti/Al/Ni/Au contacts formed on the surface of a typical InₓAl₁₋ₓN barrier layer having the same dimensions as layer 610 of FIG. 6A, at ten different current levels, the same current levels as those used for the voltage measurements shown in FIG. 6B. By comparing the graphs in FIGS. 6B and 6C, it can be seen that the current-voltage characteristic of the typical InₓAl₁₋ₓN barrier layer without indium precipitates is not as linear as that of contact and barrier layer 610, and thus not as predictable or reliable. Also, the variation among the voltage measurements of the different pairs of contacts at the same current values is larger than the variations shown in FIG. 6A, which shows that the performance of contacts formed on a typical InₓAl₁₋ₓN barrier layer is not as repeatable as the performance of contacts formed on an InₓAl₁₋ₓN contact and barrier layer having indium precipitates. Thus it can be seen that indium-containing contact and barrier layer 610 having indium precipitates allows for better reliability and repeatability of metal source and drain contacts for a HEMT device than a typical InₓAl₁₋ₓN barrier layer without indium precipitates.

What is claimed is:

1. A high electron mobility transistor device comprising:
a channel layer; and
a contact and barrier layer on the channel layer, the contact and barrier layer made of indium aluminum nitride having a plurality of indium precipitates exposed at the surface of the contact and barrier layer.

2. The high electron mobility transistor device of claim 1, wherein the contact and barrier layer is an epitaxial layer.

3. The high electron mobility transistor device of claim 1, further comprising at least one metal contact on the contact and barrier layer that forms an ohmic contact with at least one of the plurality of indium precipitates.

4. The high electron mobility transistor device of claim 1, wherein the channel layer is made of gallium nitride.

5. The high electron mobility transistor device of claim 1, wherein the plurality of indium precipitates extend below the surface of the contact and barrier layer.

6. The high electron mobility transistor device of claim 1, wherein the plurality of indium precipitates are substantially randomly distributed across a surface of the contact and barrier layer.

7. The high electron mobility transistor device of claim 1, wherein each of the plurality of indium precipitates has a diameter at the surface of the contact and barrier layer in the range of about 10 nanometers to 350 nanometers.

8. The high electron mobility transistor device of claim 1, wherein the contact and barrier layer includes a lower portion that does not include indium precipitates and an upper portion that includes the plurality of indium precipitates exposed at the surface of the contact and barrier layer.

9. The high electron mobility transistor device of claim 8, wherein a thickness of the lower portion of the contact and barrier layer is greater than the thickness of the upper portion of the contact and barrier layer.

10. The high electron mobility transistor device of claim 9, further comprising a buffer layer between a substrate and the channel layer.

11. The high electron mobility transistor device of claim 10, further comprising an insulating layer on the contact and barrier layer and a gate structure on the insulating layer.

12. A method of fabricating a high electron mobility transistor device comprising:
forming a channel layer; and
forming a contact and barrier layer of indium aluminum nitride on the channel layer in growth conditions such that a plurality of indium precipitates exposed on the surface of the contact and barrier layer are formed.

13. The method of claim 12, wherein forming the contact and barrier layer includes epitaxially growing indium aluminum nitride using a metal organic chemical vapor deposition process having a low ratio of group-V precursors to group-III precursors and a flow rate of an indium precursor greater than a flow rate of an aluminum precursor.

14. The method of claim 12, wherein forming the contact and barrier layer includes epitaxially growing indium aluminum nitride using a metal organic chemical vapor deposition process having a ratio of group-V precursors to group-III precursors of about 1400 and a flow rate of an indium precursor about 4 times greater than a flow rate of an aluminum precursor.

15. The method of claim 12, wherein forming the contact and barrier layer includes epitaxially growing indium aluminum nitride using a metal organic chemical vapor deposition process having a ratio of ammonia to trimethylindium and trimethylaluminum of 1404.2 and a flow rate of trimethylindium 4.5 times greater than a flow rate of trimethylaluminum.

16. The method of claim 12, wherein forming the contact and barrier layer includes epitaxially growing indium aluminum nitride using a metal organic chemical vapor deposition process having a flow rate of ammonia of 2.23 E+05 μmol/min, a flow rate of trimethylaluminum of 29.0 μmol/min, and flow rate of trimethylaluminum of 129.8 μmol/min.

17. The method of claim 12, further comprising forming at least one metal contact on the contact and barrier layer such that the at least one metal contact forms an ohmic contact with at least one of the plurality of indium precipitates.

18. The method of claim 12, wherein forming the channel layer comprises epitaxially growing a layer of gallium nitride.

19. The method of claim 12, wherein forming the contact and barrier layer comprises
forming a first portion of the contact and barrier layer of indium aluminum nitride in first growth conditions such that indium precipitates do not form, and
forming a second portion of contact and barrier layer of indium aluminum nitride in second growth conditions such that the plurality of indium precipitates exposed at the surface of the contact and barrier layer form.

20. The method of claim 19, wherein a thickness of the first portion of the contact and barrier layer is greater than a thickness of the second portion of the contact and barrier layer.

21. The method of claim 20, wherein the second portion of the contact and barrier layer has a thickness of at least about 100 Angstroms.

22. The method of claim 20, wherein the thickness of the first portion of the contact and barrier layer is about two-thirds of the total thickness of the contact and barrier layer and the thickness of the second portion of the contact and barrier layer is about one-third of the total thickness of the contact and barrier layer.
